(19) United States
(12) Patent Application Publication
(10) Pub. No.: US 2024/0430986 A1
(43) Pub. Date: Dec. 26, 2024

(54) HEAT TREATMENT APPARATUS AND TEMPERATURE REGULATING METHOD FOR SEMICONDUCTOR WORKPIECE

(71) Applicant: Beijing E-Town Semiconductor Technology Co., Ltd., Beijing (CN)

(72) Inventors: Wenyan WANG, Beijing (CN); Dongjian LI, Beijing (CN); Jianmin JI, Beijing (CN); Liang ZHAO, Beijing (CN)

(21) Appl. No.: 18/679,715

(22) Filed: May 31, 2024

(30) Foreign Application Priority Data
Jun. 26, 2023 (CN) 202310763577.7

(51) Int. Cl. H05B 1/02; F27B 17/00; G01J 5/08; G01J 5/10; H01L 21/67

(52) U.S. Cl. CPC H05B 1/0233; F27B 17/0025; G01J 5/0896; G01J 5/10; H01L 21/67115; H01L 21/67248

(57) ABSTRACT

A heat treatment apparatus is provided, which includes: a first cover plate including three or more first windows; a second cover plate including two or more second windows, the second windows are transmissive to radiation with a wavelength of 2.7 μm; a workpiece support element between the first cover plate and the second cover plate, configured to support the semiconductor workpiece; a temperature measurement component comprising an infrared emitter, at least two infrared reflection sensors that are successive and at least two infrared transmission sensors, where the three or more first windows comprise a first window at a first position, a first window at least one middle position and a first window at a final position in a horizontal direction away from the infrared emitter, and a surface facing to the second cover plate of the first window at the middle position has a reflection transmission coating layer.

### CROSS-REFERENCE TO RELATED APPLICATIONS

The present application claims priority to Chinese Patent Application No. CN202310763577.7, filed with the China National Intellectual Property Administration on Jun. 26, 2023, the disclosure of which is hereby incorporated herein by reference in its entirety.

### TECHNICAL FIELD

The present disclosure relates to the field of semiconductor processing technology, in particular, to the field of heat treatment of semiconductor workpieces.

### BACKGROUND

Heating temperature required for a semiconductor workpiece in a heat treatment process is usually around 400° C. to 1200° C. In a rapid heat treatment process, lamp arrays are usually used to preform heat treatment on the semiconductor workpiece in a double-sided heating method. Reliable and accurate measurement of temperature of the workpiece is crucial in the heat treatment process.

### SUMMARY

The present disclosure provides a heat treatment apparatus and an accurate measurement method for a semiconductor workpiece.

According to an aspect of the present disclosure, a heat treatment apparatus for a semiconductor workpiece is provided, which includes:
one or more heating elements configured to heat the semiconductor workpiece;
a first cover plate including three or more first windows;
a second cover plate including two or more second windows, the second windows are transmissive to radiation with a wavelength of 2.7 μm;
a workpiece support element between the first cover plate and the second cover plate, configured to support the semiconductor workpiece;
a temperature measurement component including an infrared emitter, at least two infrared reflection sensors that are successive and at least two infrared transmission sensors,
where the three or more first windows includes a first window at a first position, a first window at at least one middle position and a first window at a final position in a horizontal direction away from the infrared emitter, and
a surface facing to the second cover plate of the first window at the middle position has a reflection transmission coating layer.

According to another aspect of the present disclosure, a temperature regulating method for a semiconductor workpiece is provided, which includes:
placing the semiconductor workpiece on a workpiece support element in a reaction chamber of a heat treatment apparatus;
disposing a first cover plate comprising three or more first windows;
disposing a second cover plate comprising two or more second windows,
wherein the three or more first windows comprise a first window at a first position, a first window at least one middle position and a first window at a final position in a horizontal direction away from the infrared emitter, and a surface facing to the second cover plate of the first window at the middle position has a reflection transmission coating layer;
emitting, by an infrared emitter, infrared radiation;
making the infrared radiation transmit through the first window at the first position to irradiate to a surface of the semiconductor workpiece;
receiving and measuring, by infrared reflection sensors, first portion infrared radiation amounts reflected at least two sites on the surface of the semiconductor workpiece respectively, and receiving and measuring, by infrared transmission sensors, second portion infrared radiation amounts transmitted through the at least two sites respectively;
determining reflectivity and transmissivity of the semiconductor workpiece at a site according to a first portion infrared radiation amount and a second portion infrared radiation amount at the same site, and calculating emissivity of the semiconductor workpiece by the reflectivity and the transmissivity;
calculating temperature on the surface of the semiconductor workpiece at the same site
according to the emissivity; and
regulating a heating element in a corresponding site area according to the temperature on the surface of the semiconductor.

It should be understood that the contents described in this part is not intended to identify key or important features of the embodiments of the present disclosure, nor is it intended to limit the scope of the present disclosure. The other features of the present disclosure are made easy to understand by the following description.

### BRIEF DESCRIPTION OF THE DRAWINGS

The accompanying drawings are provided for a better understanding of the present scheme and do not constitute a limitation of the present disclosure.

FIG. 1 is a top view of a heat treatment apparatus according to an embodiment of the present disclosure;

FIG. 2 is a cross-section view of a heat treatment apparatus according to an embodiment of the present disclosure;

FIG. 3 is a schematic diagram of a lamp group partition in a heat treatment apparatus according to an embodiment of the present disclosure;

FIG. 4 is a schematic diagram of positions of an infrared emitter, an infrared reflection sensor and an infrared transmission sensor in a heat treatment apparatus according to an embodiment of the present disclosure.

### DETAILED DESCRIPTION

Hereinafter, explanation of exemplary embodiments of the present disclosure will be made in conjunction with the accompanying drawings, which includes various details of the embodiments of the present disclosure to facilitate understanding and should be considered merely exemplary. Therefore, those having ordinary skill in the art should recognize that various changes and modifications may be made to the embodiments described herein without departing from the scope of the present disclosure. Similarly, for clarity and conciseness, descriptions of well-known functions and structures are omitted in the following descriptions.

A heat treatment process for a semiconductor workpiece described in the present disclosure may be, for example, a rapid thermal annealing process. Due to different light absorption coefficients of different materials (such as Si, SiO₂, SiN and the like) on the semiconductor workpiece, for example, a wafer, when heating a front side of the semiconductor workpiece by using a single-sided radiation method, a pattern effect will be generated. Therefore, a double-sided heating manner is usually used to reduce uneven heating of temperature of the wafer caused by the pattern effect.

On the other hand, in the rapid thermal annealing process, a non-contact temperature measuring method is used to measure temperature of the semiconductor workpiece. Setting of heating elements (such as lamp groups) for double-sided heating of the wafer allows the semiconductor workpiece to be completely covered by radiation of the heating elements. However, measurement of the temperature of the semiconductor workpiece by the non-contact temperature measuring method will be interfered by light emitted by the heating elements and reflected and transmitted through the semiconductor workpiece, and robustness of the measurement of the temperature will be improved.

The semiconductor workpiece is usually transmissive in an infrared band at normal workpiece temperature and does not emit significant blackbody radiation. Conventional radiation measurement methods pose difficulties in the measurement of the temperature of the semiconductor workpiece at temperature below 750° C. due to a large error in measurable blackbody radiation emitted by the workpiece.

According to an aspect of the present disclosure, a heat treatment apparatus for the semiconductor workpiece is provided, which includes:
one or more heating elements configured to heat the semiconductor workpiece;
a first cover plate including three or more first windows;
a second cover plate including two or more second windows, the second windows are transmissive to radiation with a wavelength of 2.7 μm;
a workpiece support element between the first cover plate and the second cover plate, configured to support the semiconductor workpiece;
a temperature measurement component including an infrared emitter, at least two infrared reflection sensors that are successive and at least two infrared transmission sensors, where the three or more first windows include a first window at a first position, a first
window at at least one middle position and a first window at a final position in a horizontal direction away from the infrared emitter, and
a surface facing to the second cover plate of the first window at the middle position has a reflection transmission coating layer.

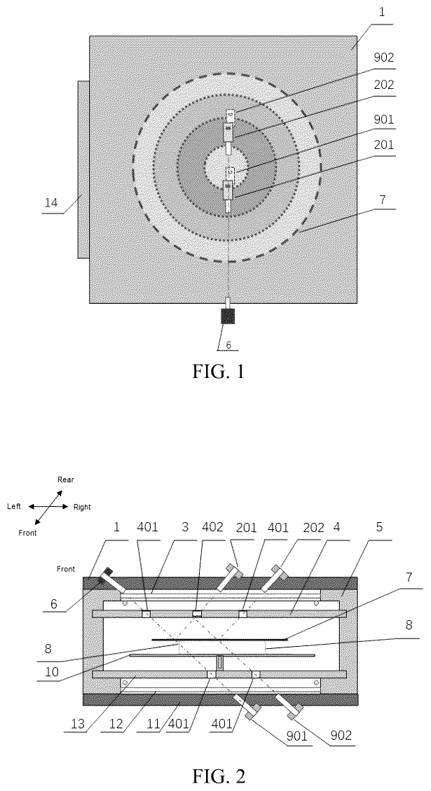

Specifically, referring to FIGS. 1 and 2, the heat treatment apparatus according to an embodiment of the present disclosure includes a top plate 1, a bottom plate 11, an upper heating lamp group 3, a lower heating lamp group 12, an upper cover plate 4 having windows, a lower cover plate 13 having windows, a reaction chamber body 5, a workpiece support element such as a quartz support plate 10 and a hold needle 8, an infrared emitter 6 and at least two infrared reflection sensors 201 and 202 disposed at an outer side (a side facing away from a reaction chamber) of the top plate 1, at least two infrared transmission sensors 901 and 902 disposed at an outer side (a side facing away from the reaction chamber) of the bottom plate 11, and a reaction chamber door 14.

Specifically, both the upper cover plate 4 and the lower cover plate 13 of the present disclosure may adopt a high hydroxyl quartz cover plate, so that infrared light of 2.7 μm emitted by the heating lamp groups can be filtered out, thereby reducing an impact of radiation from the heating lamp groups on the temperature of the semiconductor workpiece.

The upper cover plate 4 is disposed with at least three windows, windows 401 at two ends (that is, the window at the first position and the window at the final position) are not covered by the reflection transmission coating layer, and the surface facing to the semiconductor workpiece of the window 402 at the at least middle position has the reflection transmission coating layer. In the present disclosure, the upper cover plate 4 preferably adopts the reflection transmission coating layer, non-window areas are not transmissive to the infrared light with the wavelength of 2.7 μm, window areas are transmissive to the infrared light with the wavelength of 2.7 μm, and a window area having the reflection transmission coating layer is reflexible and transmissive to the infrared light with the wavelength of 2.7 μm.

The above reflection transmission coating layer has reflectivity of 10% to 50% (such as 15%, 20%, 25%, 30%, 35%, 40% or 45%) and transmissivity of 50% to 90% (such as 55%, 60%, 65%, 70%, 75%, 80% or 85%) to the radiation with the wavelength of 2.7 μm.

According to a specific implementation, the above reflection transmission coating layer may be a metal halide layer, preferably an alkali metal halide layer, and more specifically, a potassium bromide layer.

The heat treatment apparatus of the present disclosure is disposed with at least one infrared emitter 6, which may emit the infrared light with the wavelength of 2.7 μm to the semiconductor workpiece, at an end of the outer side of the top plate 1.

The infrared light emitted by the above infrared emitter 6 transmits through the window 401 at the first position in the upper cover plate 4 and irradiates to a first site on a surface of the semiconductor workpiece 7. Where the semiconductor workpiece 7 partially reflects and partially transmits the infrared light of this wavelength, infrared light transmitted through the first site on the surface of the semiconductor workpiece irradiates to the window 401 in the lower cover plate 13, further transmits through this window and then irradiates to a first infrared transmission sensor 901; infrared light reflected at the first site on the surface of the semiconductor workpiece irradiates to the window 402 having the reflection transmission coating layer at the middle position in the upper cover plate 4, then further irradiates to a second site on the semiconductor workpiece by being reflected by this window; infrared light transmitted through the window 402 having the reflection transmission coating layer irradiates to a first infrared reflection sensor 201.

Infrared light irradiated to the second site on the semiconductor workpiece by being reflected by the window 402 having the reflection transmission coating layer is reflected by the semiconductor workpiece and transmitted through the semiconductor workpiece again; a transmitted part of the infrared light irradiates to the window in the lower cover plate and then irradiates to a second infrared transmission sensor; a reflected part of the infrared light is reflected to the window in the upper cover plate which has or does not have the reflection transmission coating layer, if this window does not have the reflection transmission coating layer, the reflected part of the infrared light irradiates to a second reflection sensor by transmitting through this window, if this window has the reflection transmission coating layer, a process of reflecting and transmitting reflected infrared light at a next site on the semiconductor workpiece is repeated again.

In the heat treatment apparatus of the present disclosure, only one infrared emitter is disposed, cyclic reflection may be repeated at least twice by using reflection performance of the semiconductor workpiece and the reflection transmission coating layer, and both the reflection sensor and the transmission sensor are disposed for the same site to achieve real-time and accurate measurement of temperature at multiple sites on the semiconductor workpiece, where times of the cyclic reflection may be determined according to a temperature requirement. Thus, it is possible to achieve as many measurement sites as possible, thereby improving accuracy of temperature measurement and control.

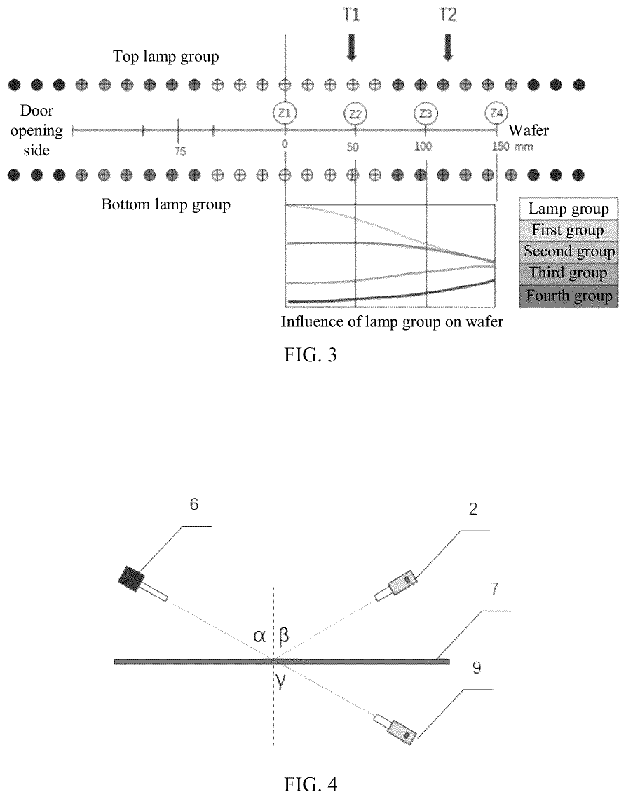

Furthermore, referring to FIGS. 3 and 4, with respect to a longitudinal axis of the semiconductor workpiece (or a longitudinal axis of the reaction chamber), an angle α of the infrared emitter 6 to the longitudinal axis, an angle β of the infrared reflection sensor 2 to the longitudinal axis and an angle γ of the infrared transmission sensor 9 to the longitudinal axis are 30° to 60° respectively, for example, 45°. Where the infrared emitter 6 and the infrared transmission sensor 9 are located at a same straight line.

The above infrared emitter, infrared reflection sensor and infrared transmission sensor jointly constitute a semiconductor workpiece emissivity measurement system without influence of heating lamps, thereby promoting accurate measurement of the temperature of the semiconductor workpiece, especially accurate measurement of medium temperature between 400° C. and 750° C.

According to another aspect of the present disclosure, a temperature regulating method for the semiconductor workpiece is provided, which includes steps of:
placing the semiconductor workpiece on a workpiece support element in a reaction chamber of a heat treatment apparatus;
disposing a first cover plate including three or more first windows;
disposing a second cover plate including two or more second windows,
where the three or more first windows include a first window at a first position, a first window at at least one middle position and a first window at a final position in a horizontal direction away from the infrared emitter, and a surface facing to the second cover plate of the first window at the middle position has a reflection transmission coating layer;
emitting, by an infrared emitter, infrared radiation;
making the infrared radiation transmit through the first window at the first position to irradiate to a surface of the semiconductor workpiece;
receiving and measuring, by infrared reflection sensors, first portion infrared radiation amounts reflected at at least two sites on the surface of the semiconductor workpiece respectively, and receiving and measuring, by infrared transmission sensors, second portion infrared radiation amounts transmitted through the at least two sites respectively;
determining reflectivity and transmissivity of the semiconductor workpiece at a site according to a first portion infrared radiation amount and a second portion infrared radiation amount at the same site, and calculating emissivity of the semiconductor workpiece by the reflectivity and the transmissivity;
calculating temperature on the surface of the semiconductor workpiece at the same site according to the emissivity;
regulating a heating element in a corresponding site area according to the temperature on the surface of the semiconductor.

According to a specific implementation, in the above steps, the infrared radiation is made transmit through the first window (which does not have the reflection transmission coating layer) at the first position to irradiate to a first site on the surface of the semiconductor workpiece, an infrared reflection sensor receives and measures a first portion infrared reflection radiation amount reflected by the semiconductor workpiece at the first site and then transmitted through the first window (which has the reflection transmission coating layer) at the middle position, and an infrared transmission sensor receives and determines a first portion infrared transmission radiation amount transmitted through the semiconductor workpiece at the first site and then transmitted through a second window;
infrared radiation reflected by the semiconductor workpiece at the first site and then irradiated to the first window at the middle position is partially reflected to a second site on the surface of the semiconductor workpiece, an infrared reflection sensor receives and measures a second portion infrared reflection radiation amount reflected by the semiconductor workpiece at the second site and then transmitted through the first window at the middle position or the final position, and an infrared transmission sensor receives and determines a second portion infrared transmission radiation amount transmitted through the semiconductor workpiece at the second site and then transmitted through a second window;
emissivity of the semiconductor workpiece at the first site is calculated according to the first portion infrared reflection radiation amount and the first portion infrared transmission radiation amount, and then temperature of the semiconductor workpiece at the first site is calculated;
emissivity of the semiconductor workpiece at the second site is calculated according to the second portion infrared reflection radiation amount and the second portion infrared transmission radiation amount, and then temperature of the semiconductor workpiece at the second site is calculated.

The infrared light with the wavelength of 2.7 μm emitted by the infrared emitter may be modulated into pulsed light by using a chopper, the pulsed light with the wavelength of 2.7 μm is irradiated on the semiconductor workpiece (wafer) 7, a reflected portion is received by the infrared reflection sensor 2 of 2.7 μm, a transmitted portion is received by the infrared transmission sensor 9 of 2.7 μm. It is calculated that the sum of emissivity, reflectivity and transmissivity of an object is 1 by the following formula (1):

$$ε ( λ ) + ρ ( λ ) + τ ( λ ) = 1 \qquad ( 1 )$$

Real-time reflectivity p and transmissivity t of the wafer are determined by the infrared reflection sensor 2 having the wavelength λ of 2.7 μm and the infrared transmission sensor 9 having the wavelength of 2.7 μm, and emissivity & of the wafer is calculated. The reflectivity p is a ratio of an intensity of the reflected light detected by the infrared reflection sensor to an intensity of the infrared light emitted by the infrared emitter, and the transmissivity t is a ratio of an intensity of the transmitted light detected by the infrared transmission sensor to the intensity of the infrared light emitted by the infrared emitter.

Meanwhile, the infrared reflection sensor 2 and the infrared transmission sensor 9 mentioned above may also receive infrared light from thermal radiation on upper and lower surfaces of the wafer, and this radiated light may be distinguished from the light emitted by the infrared emitter 6 in terms of frequency. The temperature on the front side and the back side of the wafer is calculated based on the following blackbody radiation formula (2):

$$T = \frac{h c}{λ k} \cdot \frac{1}{ln ( \frac{2 π h {c}^{2} Δ λ}{{λ}^{5}} \cdot \frac{ε}{{I}_{Wafer}} + 1 )} \qquad ( 2 )$$

Where I_{wafer} is the received infrared thermal radiation of the wafer, h is the Planck constant, c is the speed of light, and k is the Boltzmann constant, λ is a radiation wavelength, ε is the emissivity of the wafer.

After the wafer enters a rapid heat treatment chamber and begins being heated, the infrared emitter 6 of 2.7 μm, the infrared reflection sensor 2 of 2.7 μm and the infrared transmission sensor 9 of 2.7 μm continuously measure the reflectivity, the emissivity and the transmissivity of the wafer. A temperature test result obtained from this test may provide a reference temperature within a temperature range of 250° C.-400° C. of the wafer, and a temperature rise state of the wafer may be monitored in real time. When process temperature is between 400° C.-750° C., the infrared emitter 6 of 2.7 μm, the infrared reflection sensor 2 of 2.7 μm and the infrared transmission sensor 9 of 2.7 μm may accurately calculate the temperature of the wafer, facilitating closed-loop control of the temperature of the wafer. When wafer process temperature is above 750° C., the above infrared emitter 6 of 2.7 μm, infrared reflection sensor 2 of 2.7 μm and infrared transmission sensor of 2.7 μm may use a traditional method to measure the temperature of the wafer.

According to the above method of the present disclosure, stability of temperature measurement and control of the heat treatment apparatus may be improved under conditions such as low emissivity (<0.3) of the semiconductor workpiece, sudden change in the emissivity of semiconductor workpiece (such as a polycrystalline silicon layer on the wafer undergoes phase transition during being heated). Meanwhile, a measurement range of the semiconductor workpiece temperature may be extended as low as 250° C.

Preferably, accurately measurable temperature of the aforementioned semiconductor workpiece is within the range of 400° C.-750° C.

In the above method, regulating the heating element in the corresponding site area according to the temperature on the surface of the semiconductor includes adjusting a power of the heating element in the corresponding site area.

Referring to FIG. 3, the heat treatment apparatus of the present disclosure includes two heating lamp arrays, namely a top lamp group and a bottom lamp group. Each heating lamp array is divided into four groups (indicated by light to dark in gray color). Meanwhile, the reaction chamber is symmetrically divided into two parts from a door opening side to the wafer, and an area between the center and the wafer is divided into four temperature measurement areas Z1 to Z4.

For example, according to the method of the present disclosure, temperature of areas Z2 and Z3 of the wafer may be measured to obtain T1 and T2, and the measured temperature may be compared with preset temperature. If the measured temperature is not within the preset temperature range, power of one or both of the top and bottom lamp groups may be adjusted to regulate the temperature of the wafer to the preset temperature.

In the method of the present disclosure, only one infrared emitter needs to be disposed, and a plurality of infrared reflection sensors and a plurality of infrared transmission sensors need to be disposed at the same time, which may increase a number of temperature measurement sites, broaden a temperature range of a test, and thereby improving accuracy of a temperature test. Based on the measured temperature at different sites of the semiconductor workpiece, the lamp groups corresponding to the sites may be independently controlled to achieve accurate temperature control

According to another implementation of the present disclosure, one pyrometer may be disposed in each of the two areas, and a suitable wafer model may be used to select the suitable wafer model for the two measured temperature values. The corresponding four temperatures may be simulated for the four wafer areas corresponding to the four lamp groups. That is, according to the method of the present disclosure, more temperature values may be obtained by measuring temperature t fewer sites, thereby more accurately controlling the temperature of the wafer and improving temperature control accuracy.

According to the heat treatment device and temperature regulate method of the present disclosure, real-time and accurate detection may be carried out in the rapid heat treatment process, and the heating elements corresponding to the measurement sites may be adjusted in a timely manner, thereby keeping the temperature of the semiconductor workpiece within the predetermined range throughout the process.

It should be understood that various forms of processes shown above may be used to reorder, add, or delete steps. For example, the steps recorded in the present disclosure may be executed in parallel, sequentially, or in different orders, as long as the expected results of the technical solution disclosed by the present disclosure may be achieved, which is not limited herein.

The above specific implementations do not constitute a limitation on the protection scope of the present disclosure. Those having ordinary skill in the art should understand that various modifications, combinations, sub combinations, and substitutions may be made based on design requirements and other factors. Any modifications, equivalent substitutions, and improvements made within the principle of the present disclosure should be included within the protection scope of the present disclosure.

What is claimed is:

1. A heat treatment apparatus for a semiconductor workpiece, comprising:
one or more heating elements configured to heat the semiconductor workpiece;
a first cover plate comprising three or more first windows;
a second cover plate comprising two or more second windows, the second windows are transmissive to radiation with a wavelength of 2.7 μm;
a workpiece support element between the first cover plate and the second cover plate, configured to support the semiconductor workpiece;
a temperature measurement component comprising an infrared emitter, at least two infrared reflection sensors that are successive and at least two infrared transmission sensors,
wherein the three or more first windows comprise a first window at a first position, a first window at least one middle position and a first window at a final position in a horizontal direction away from the infrared emitter, and
a surface facing to the second cover plate of the first window at the middle position has a reflection transmission coating layer.

2. The heat treatment apparatus of claim 1, wherein the reflection transmission coating layer has a reflectivity of 10%-50% and a transmissivity of 50%-90% for the radiation with the wavelength of 2.7 μm.

3. The heat treatment apparatus of claim 1, wherein the reflection transmission coating layer is a potassium bromide layer.

4. The heat treatment apparatus of claim 2, wherein the reflection transmission coating layer is a potassium bromide layer.

5. The heat treatment apparatus of claim 1, where in the at least two infrared reflection sensors that are successive receive infrared radiations that are came from the infrared emitter and then reflected by the semiconductor workpiece and transmitted through the first windows, respectively.

6. The heat treatment apparatus of claim 2, where in the at least two infrared reflection sensors that are successive receive infrared radiations that are came from the infrared emitter and then reflected by the semiconductor workpiece and transmitted through the first windows, respectively.

7. The heat treatment apparatus of claim 1, wherein the at least two infrared transmission sensors receive radiations that are came from the infrared emitter and then transmitted through the semiconductor workpiece and the second windows.

8. The heat treatment apparatus of claim 2, wherein the at least two infrared transmission sensors receive radiations that are came from the infrared emitter and then transmitted through the semiconductor workpiece and the second windows.

9. The heat treatment apparatus of claim 1, further comprises: a top plate and a bottom plate,
wherein the infrared emitter and the at least two infrared reflection sensors that are successive are disposed at an outer side of the top plate, and the at least two infrared transmission sensors are disposed at an outer side of the bottom plate.

10. The heat treatment apparatus of claim 2, further comprises: a top plate and a bottom plate,
wherein the infrared emitter and the at least two infrared reflection sensors that are successive are disposed at an outer side of the top plate, and the at least two infrared transmission sensors are disposed at an outer side of the bottom plate.

11. The heat treatment apparatus of claim 9, wherein the first cover plate and the second cover plate are high hydroxyl quartz cover plates, respectively.

12. The heat treatment apparatus of claim 10, wherein the first cover plate and the second cover plate are high hydroxyl quartz cover plates, respectively.

13. The heat treatment apparatus of claim 1, wherein the heat treatment apparatus is capable of accurately measure temperature of the semiconductor workpiece within a range of 400° C.-750° C.

14. The heat treatment apparatus of claim 2, wherein the heat treatment apparatus is capable of accurately measure temperature of the semiconductor workpiece within a range of 400° C.-750° C.

15. The heat treatment apparatus of claim 1, further comprises: a reaction chamber defined by a reaction chamber body, the first cover plate, and the second cover plate,
wherein an angle between the infrared emitter and a longitudinal axis of the reaction chamber body, angles between the infrared reflection sensors and the longitudinal axis of the reaction chamber body and angles between the infrared transmission sensors and the longitudinal axis of the reaction chamber body are same, preferably between 30° to 60°.

16. The heat treatment apparatus of claim 1, wherein the first cover plate and the second cover plate are high hydroxyl quartz cover plates, respectively.

17. A temperature regulating method for a semiconductor workpiece, comprising:
placing the semiconductor workpiece on a workpiece support element in a reaction chamber of a heat treatment apparatus;
disposing a first cover plate comprising three or more first windows;
disposing a second cover plate comprising two or more second windows,
wherein the three or more first windows comprise a first window at a first position, a first window at least one middle position and a first window at a final position in a horizontal direction away from an infrared emitter, and a surface facing to the second cover plate of the first window at the middle position has a reflection transmission coating layer;
emitting, by an infrared emitter, infrared radiation;
making the infrared radiation transmit through the first window at the first position to irradiate to a surface of the semiconductor workpiece;
receiving and measuring, by infrared reflection sensors, first portion infrared radiation amounts reflected at least two sites on the surface of the semiconductor workpiece respectively, and receiving and measuring, by infrared transmission sensors, second portion infrared radiation amounts transmitted through the at least two sites respectively;
determining reflectivity and transmissivity of the semiconductor workpiece at a site according to a first portion infrared radiation amount and a second portion infrared radiation amount at the same site, and calculating emissivity of the semiconductor workpiece by the reflectivity and the transmissivity;
calculating temperature on the surface of the semiconductor workpiece at the same site according to the emissivity; and
regulating a heating element in a corresponding site area according to the temperature on the surface of the semiconductor.

18. The temperature regulating method of claim 17, wherein
the infrared radiation is made transmit through the first window at the first position to irradiate to a first site on the surface of the semiconductor workpiece, an infrared reflection sensor receives and measures a first portion infrared reflection radiation amount reflected by the semiconductor workpiece at the first site and then transmitted through the first window at the middle position, and an infrared transmission sensor receives and determines a first portion infrared transmission radiation amount transmitted through the semiconductor workpiece at the first site and then transmitted through a second window;
infrared radiation reflected by the semiconductor workpiece at the first site and then irradiated to the first window at the middle position is partially reflected to a second site on the surface of the semiconductor workpiece, an infrared reflection sensor receives and measures a second portion infrared reflection radiation amount reflected by the semiconductor workpiece at the second site and then transmitted through the first window at the middle position or the final position, and an infrared transmission sensor receives and determines a second portion infrared transmission radiation amount transmitted through the semiconductor workpiece at the second site and then transmitted through a second window;
emissivity of the semiconductor workpiece at the first site is calculated according to the first portion infrared reflection radiation amount and the first portion infrared transmission radiation amount, and then temperature of the semiconductor workpiece at the first site is calculated;
emissivity of the semiconductor workpiece at the second site is calculated according to the second portion infrared reflection radiation amount and the second portion infrared transmission radiation amount, and then temperature of the semiconductor workpiece at the second site is calculated.

19. The temperature regulating method of claim 17, wherein the temperature of the semiconductor workpiece is within a range of 400° C.-750° C.

20. The temperature regulating method of claim 17, wherein regulating the heating element in the corresponding site area according to the temperature on the surface of the semiconductor comprising adjusting a power of the heating element in the corresponding site area.
